(19) United States
(12) Patent Application Publication
(10) Pub. No.: US 2023/0073554 A1
(43) Pub. Date: Mar. 9, 2023

(54) CIRCUIT-BOARD COMPONENT AND MANUFACTURING METHOD THEREOF, AND LIGHT-EMITTING COMPONENT AND MANUFACTURING METHOD THEREOF

(71) Applicant: CHONGQING KONKA PHOTOELECTRIC TECHNOLOGY RESEARCH INSTITUTE CO., LTD., Chongqing (CN)

(72) Inventors: Feng ZHAI, Chongqing (CN); CHUN-LUNG HSIAO, Chongqing (CN)

(21) Appl. No.: 17/986,407

(22) Filed: Nov. 14, 2022

Related U.S. Application Data
(63) Continuation of application No. PCT/CN2021/108411, filed on Jul. 26, 2021.

(51) Int. Cl. H01L 25/075; H01L 33/00; H01L 21/66

(52) U.S. Cl. CPC H01L 25/0753; H01L 33/0093; H01L 22/22; H01L 2933/0016

(57) ABSTRACT

A circuit-board component and a manufacturing method thereof, and a light-emitting component and a manufacturing method thereof are provided in the disclosure. The light-emitting component includes the circuit-board component. The circuit-board component includes a circuit hoard, where multiple chip bonding areas are defined on the circuit board, and a weakening layer disposed on the circuit board and defining multiple cavities, where one chip bonding area corresponds to one cavity.

### CROSS-REFERENCE TO RELATED APPLICATION(S)

This application is a continuation of International Application No. PCT/CN2021/108411, filed Jul. 26, 2021, the disclosure of which is hereby incorporated by reference in its entirety.

### TECHNICAL FIELD

This application relates to the field of light-emitting chip, and more particularly to a circuit-board component and a manufacturing method thereof, and a light-emitting component and a manufacturing method thereof.

### BACKGROUND

Micro light-emitting diode (LED) is regarded as a new-generation display technology. Compared with existing liquid-crystal display (LCD), the micro LED has a higher photoelectric efficiency, a higher brightness, a higher contrast, and a lower power consumption, and can also realize flexible display in conjunction with a flexible panel.

A micro LED display panel includes multiple subpixel rendering (SPR)-based pixel areas, each SPR-based pixel area includes a red micro LED chip, a blue micro LED chip, and a green micro LED chip. During manufacturing of the display panel, red micro LED chips, blue micro LED chips, and green micro LED chips need to be transferred onto a display backplane from their respective growth substrates (wafer). For example, a transfer process of micro LED chips includes the following. A surface of a temporary substrate with a first adhesive layer is attached to a surface of a growth substrate grown with red micro LED chips, and the growth substrate is stripped off, to transfer the red micro LED chips onto the temporary substrate. A surface of a transfer substrate with a second adhesive layer is attached to the surface of the temporary substrate bearing the red micro LED chips, to selectively pick up red micro LED chips from the temporary substrate. The red micro LED chips picked up by the transfer substrate are transferred into corresponding chip bonding areas on the display backplane.

The blue micro LED chips and the green micro LED chips are also transferred onto the display backplane with the above chip transfer process.

In the above chip transfer process, it needs to select two types of adhesives to manufacture the first adhesive layer and the second adhesive layer respectively, and it needs to ensure that stickiness of the first adhesive layer is lower than that of the second adhesive layer, and thus, it is difficult to find out suitable materials. Furthermore, in the above transfer process, micro LED chips need to be transferred onto the temporary substrate from the growth substrate and then onto the transfer substrate from the temporary substrate, such that a transfer efficiency is low, and a transfer cost is higher for manufacturing the temporary substrate and the transfer substrate.

Therefore, how to improve a transfer efficiency of LED chips and reduce a transfer cost has become problems to be solved.

### SUMMARY

A circuit-board component is provided. The circuit-board component includes a circuit board and a weakening layer. Multiple chip bonding areas are defined on the circuit board. Each of the multiple chip bonding areas is provided with pads corresponding to electrodes of a light-emitting chip. The weakening layer is disposed on the circuit board and defines multiple cavities. The multiple cavities are isolated from each other by the weakening layer, one chip bonding area corresponds to one cavity, and the weakening layer forms side walls and a top wall of each of the multiple cavities. The top wall is used to bear a light-emitting chip detached from a growth substrate, and after the top wall breaks under a pressure, the light-emitting chip born falls into a corresponding chip bonding area. A distance between a surface of the top wall away from the circuit board and the circuit board is greater than or equal to a height of the light-emitting chip.

A light-emitting component is further provided. The light-emitting component includes a circuit-board component and light-emitting chips in the multiple chip bonding areas. The circuit-board component includes a circuit board and a weakening layer. Multiple chip bonding areas are defined on the circuit board. Each of the multiple chip bonding areas is provided with pads corresponding to electrodes of a light-emitting chip. The weakening layer is disposed on the circuit board and defines multiple cavities. The multiple cavities are isolated from each other by the weakening layer, one chip bonding area corresponds to one cavity, and the weakening layer forms side walls and a top wall of each of the multiple cavities. The top wall is used to bear a light-emitting chip detached from a growth substrate, and after the top wall breaks under a pressure, the light-emitting chip born falls into a corresponding chip bonding area. A distance between a surface of the top wall away from the circuit board and the circuit board is greater than or equal to a height of the light-emitting chip. Each of the light-emitting chips is born on the top wall after being detached from the growth substrate, and falls into a corresponding chip bonding area after the top wall breaks under a pressure, and electrodes of each of the light-emitting chips are coupled with pads in a corresponding chip bonding area.

A manufacturing method of the above circuit-hoard component is further provided. The manufacturing method of the above circuit-board component includes the following. A sacrificial layer is formed on the circuit board, where the sacrificial layer includes multiple sacrificial-layer units separated from each other, and each of the multiple sacrificial-layer units is covered on a corresponding chip bonding area. The weakening layer that is covered on each of the multiple sacrificial-layer units is formed on the circuit board. Each of the multiple sacrificial-layer units is removed, where a space occupied by each of the multiple sacrificial-layer units is defined as the cavity.

A manufacturing method of the above light-emitting component is further provided. The manufacturing method of the above light-emitting component includes the following. A surface of the growth substrate grown with the light-emitting chips is aligned and attached to the weakening layer on the circuit board, where the light-emitting chip is contacted with a corresponding top wall after alignment and attachment. The light-emitting chip, on the growth substrate, corresponding to the top wall is stripped off from the growth substrate, and the growth substrate is removed, where the light-emitting chip stripped off is horn on the top wall. A pressure is applied to the top wall where the light-emitting chip is born, to make the top wall break and make the light-emitting chip born on the top wall fall into a corresponding chip bonding area. Electrodes of the fallen light-emitting chip are coupled with pads in a corresponding chip bonding area.

### BRIEF DESCRIPTION OF THE DRAWINGS

FIG. 1(a) is a schematic diagram illustrating respective transferring of three-color micro light-emitting diode (LED) chips onto a display backplane from a growth substrate in the related art.

FIG. 1(b) is a schematic diagram illustrating a process of transferring of red micro LED chips in the related art.

FIG. 1(c) is a schematic diagram illustrating an area where a temporary substrate is attached to a growth substrate in the related art.

FIG. 1(d) is a schematic diagram illustrating a temporary substrate bearing red micro LED chips in the related art.

FIG. 1(e) is a schematic diagram illustrating a temporary substrate after part of red micro LED chips is picked in the related art.

FIG. 1(f) is a schematic diagram illustrating a display backplane after transferring and bonding of micro LED chips are complete.

FIG. 2 is a schematic structural diagram 1 illustrating a circuit-board component provided in implementations of the disclosure.

FIG. 3 is a schematic structural diagram 2 illustrating a circuit-board component provided in implementations of the disclosure.

FIG. 4 is a schematic structural diagram 3 illustrating a circuit-board component provided in implementations of the disclosure.

FIG. 5 is a schematic flow chart illustrating a manufacturing method of a circuit-board component provided in another optional implementation of the disclosure.

FIG. 6 is a schematic diagram 1 illustrating a manufacturing process of a circuit-board component provided in another optional implementation of the disclosure.

FIG. 7 is a schematic diagram 2 illustrating a manufacturing process of a circuit-board component provided in another optional implementation of the disclosure.

FIG. 8 is a schematic structural diagram 1 illustrating a light-emitting component provided in yet another optional implementation of the disclosure.

FIG. 9 is a schematic structural diagram 2 illustrating a light-emitting component provided in yet another optional implementation of the disclosure.

FIG. 10 is a schematic structural diagram 3 illustrating a light-emitting component provided in yet another optional implementation of the disclosure.

FIG. 11 is a schematic flow chart illustrating a manufacturing method of a light-emitting component provided in another optional implementation of the disclosure.

FIG. 12 is a schematic diagram illustrating a transfer process of a first light-emitting chip provided in another optional implementation of the disclosure.

FIG. 13 is a schematic diagram illustrating a transfer process of a second light-emitting chip provided in another optional implementation of the disclosure.

FIG. 14 is a schematic diagram illustrating a transfer process of a third light-emitting chip provided in another optional implementation of the disclosure.

Description of reference signs of the accompanying drawings: 10—growth substrate, 101—micro LED chip, 102—chip vacancy, 20—temporary substrate, 201—first adhesive layer, 30—transfer substrate, 301—second adhesive layer, 302—display backplane, 4—circuit board, 40—chip bonding area, 41—pad, 5—weakening layer, 50—cavity, 51—top wall, 52—side wall, 6—light-emitting chip, 60—electrode, 61—first light-emitting chip, 62—second light-emitting chip, 63—third light-emitting chip, 7—sacrificial-layer unit, 81—first growth substrate, 82—second growth substrate, 83—third growth substrate.

### DETAILED :DESCRIPTION

In order to facilitate understanding of the disclosure, the disclosure will be described fully below with reference to accompanying drawings. The accompanying drawings illustrate exemplary implementations of the disclosure. However, the disclosure may be implemented in many different forms and is not limited to the implementations described herein. On the contrary, these implementations are provided to achieve a thorough and complete understanding of disclosed contents of the disclosure.

Unless otherwise defined, all technical and scientific terms herein have the same meaning as commonly understood by one of ordinary skill in the technical field to which the disclosure belongs. The terms herein are merely for the purpose of describing implementations of the disclosure, which are not intended to limit the disclosure.

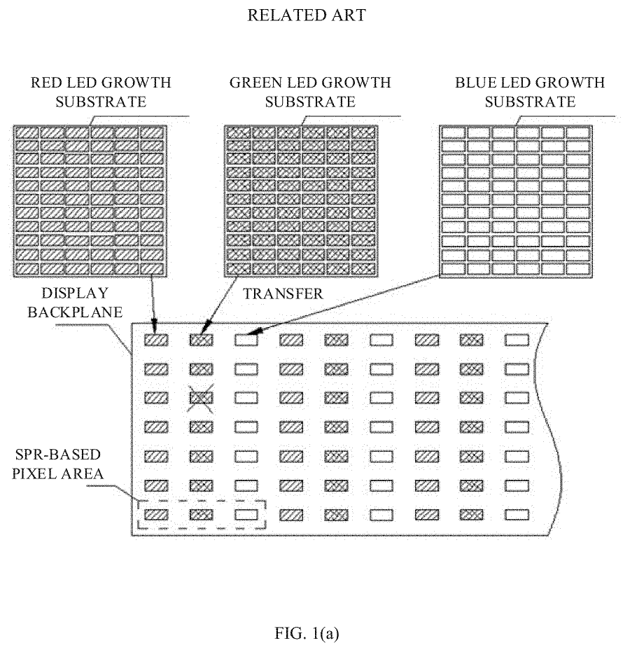

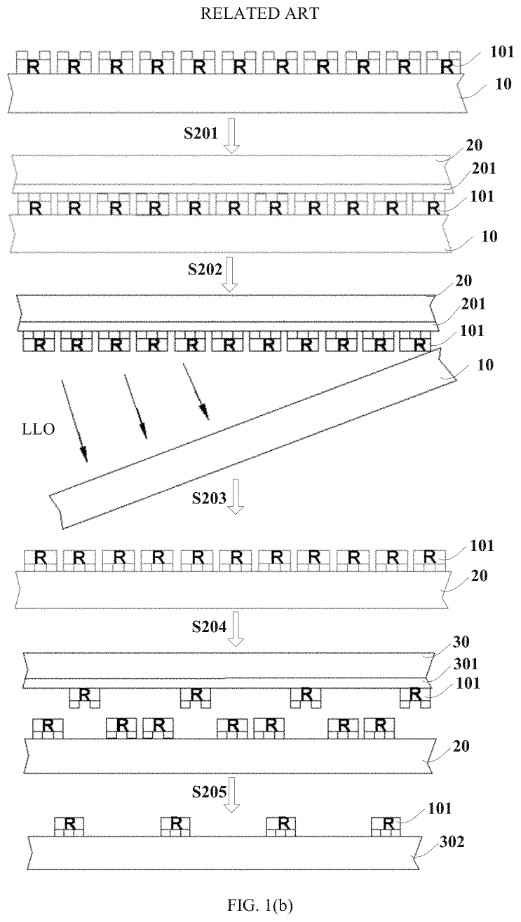

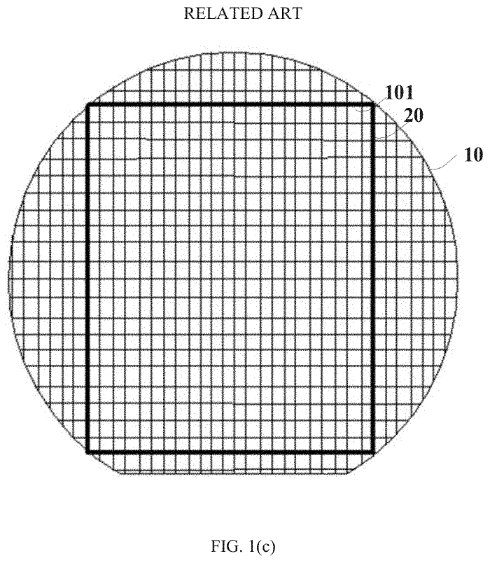

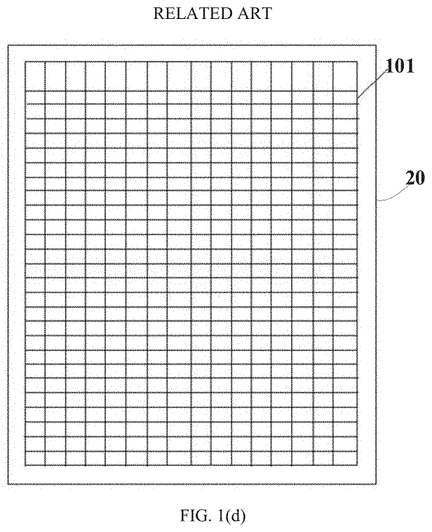

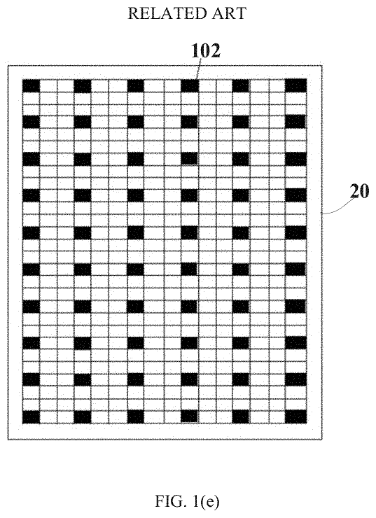

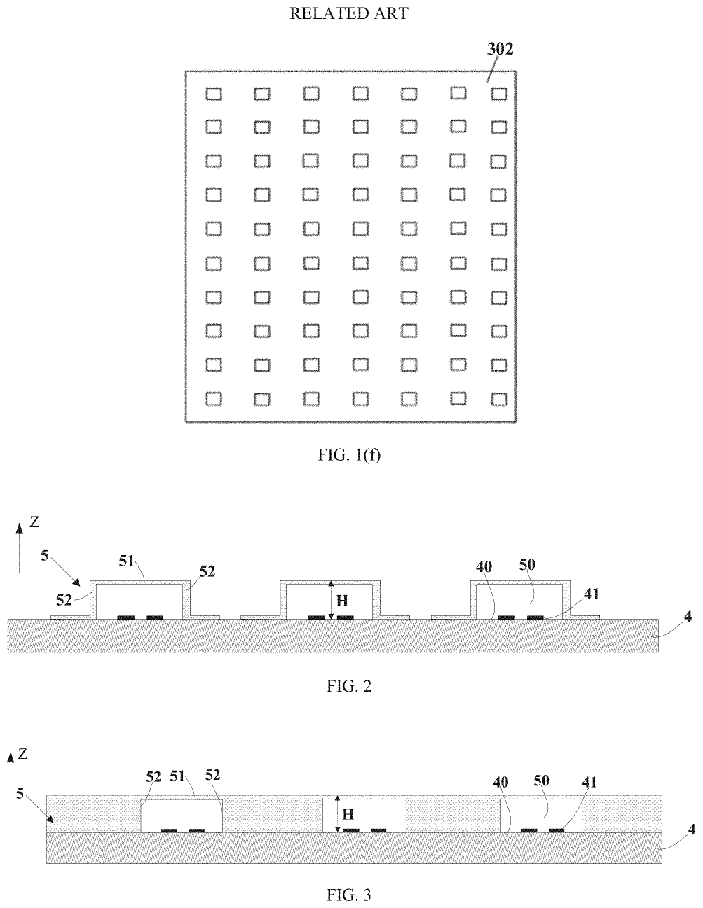

In a micro light-emitting diode (LED) display technology, as illustrated in FIG. 1(a), red micro LED chips, blue micro LED chips, and green micro LED chips need to be transferred onto a display backplane from their respective growth substrates. For example, as illustrated in FIG. 1(b) to FIG. 1(e), a transfer process of the red micro LED chips includes the following.

At S201, a surface of a temporary substrate 20 with a first adhesive layer 201 is attached to a surface of a growth substrate 10 grown with red micro LED chips 101, where a top view after attachment is illustrated in FIGS. 1(c).

At S202 to S203, the growth substrate 10 is stripped off, to transfer the red micro LED chips 101 onto the temporary substrate 20, where in this case a top view of the temporary substrate 20 is illustrated in FIG. 1(d).

At S204, a surface of a transfer substrate 30 with a second adhesive layer 301 is attached to the surface of the temporary substrate 20 bearing the red micro LED chips 101, to selectively pick up corresponding red micro LED chips 101 from the temporary substrate 20. As illustrated in FIG. 1(e), a chip vacancy 102 is generated after a red micro LED chip on the temporary substrate 20 is picked up.

At S205, the red micro LED chips picked up by the transfer substrate 30 are transferred into corresponding chip bonding areas on the display backplane 302.

The blue micro LED chips and the green micro LED chips are also transferred onto the display backplane with the above chip transfer process, and the display backplane onto which transferring of all micro LED chips is complete is illustrated in FIG. 1(f).

In the above chip transfer process, it needs to select two types of adhesives to manufacture the first adhesive layer 201 and the second adhesive layer 301 respectively, and it needs to ensure that stickiness of the first adhesive layer 201 is lower than that of the second adhesive layer 301, and thus, it is difficult to find out suitable materials. Furthermore, in the above transfer process, micro LED chips need to be transferred onto the temporary substrate 20 from the growth substrate 10 and then onto the transfer substrate 30 from the temporary substrate 20, such that a transfer efficiency is low, and a transfer cost is higher for manufacturing the temporary substrate 10 and the transfer substrate 30.

In view of the above deficiencies of the related art, the disclosure provides a circuit-board component and a manufacturing method thereof, and a light-emitting component and a manufacturing method thereof, which aim to solve problems of how to improve a transfer efficiency of LED chips and reduce a transfer cost in the related art.

The disclosure provides a circuit-board component. The circuit-board component includes a circuit board, where multiple chip bonding areas are defined on the circuit board, and each of the multiple chip bonding areas is provided with pads corresponding to electrodes of a light-emitting chip. The circuit-board component further includes a weakening layer disposed on the circuit board and defining multiple cavities, where the multiple cavities are isolated from each other by the weakening layer, one chip bonding area corresponds to one cavity, and the weakening layer forms side walls and a top wall of each of the multiple cavities. The top wall is used to bear a light-emitting chip detached from a growth substrate, and after the top wall breaks under a pressure, the light-emitting chip born falls into a corresponding chip bonding area. A distance between a surface of the top wail away from the circuit board and the circuit board is greater than or equal to a height of the light-emitting chip.

According to the circuit-board component, the circuit board of the circuit-board component is provided with the weakening layer covered on the chip bonding areas, and the weakening layer defines the cavities that are in one-to-one correspondence with the chip bonding areas and isolated from each other. During transferring of chips onto the circuit board, a surface of the growth substrate grown with light-emitting chips can be directly aligned and attached to the weakening layer, and a light-emitting chip to-be-transferred is detached from the growth substrate, such that the light-emitting chip is born on a top wall of a corresponding cavity. Then a pressure is applied to the top wall, to make the top wall break and make the light-emitting chip directly fail into a corresponding chip bonding area. Since a distance between a surface of the top wall away from the circuit board and the circuit board is greater than or equal to a height of the light-emitting chip, and the light-emitting chip transferred is located in the cavity, subsequently, when it is further required to transfer chips into other chip bonding areas on the circuit board, the light-emitting chip transferred will not interfere with other chips on the growth substrate during subsequent transferring, thereby ensuring subsequently normal transferring of light-emitting chips. As can be seen, during transferring of light-emitting chips onto the circuit-board component, it is not required to transfer light-emitting chips onto a temporary substrate from the growth substrate and then onto the transfer substrate from the temporary substrate, and also not required to manufacture the temporary substrate and the transfer substrate, such that a transfer efficiency is higher, and a transfer cost is lower.

Based on the same inventive concept, the disclosure further provides a light-emitting component. The light-emitting component includes a circuit-board component and light-emitting chips in the multiple chip bonding areas. The circuit-board component includes a circuit board, where multiple chip bonding areas are defined on the circuit board, and each of the multiple chip bonding areas is provided with pads corresponding to electrodes of a light-emitting chip. The circuit-board component further includes a weakening layer disposed on the circuit board and defining multiple cavities, where the multiple cavities are isolated from each other by the weakening layer, one chip bonding area corresponds to one cavity, and the weakening layer forms side walls and a top wall of each of the multiple cavities. The top wall is used to bear a light-emitting chip detached from a growth substrate, and after the top wall breaks under a pressure, the light-emitting chip born falls into a corresponding chip bonding area. A distance between a surface of the top wall away from the circuit board and the circuit board is greater than or equal to a height of the light-emitting chip. Each of the light-emitting chips is born on the top wall after being detached from the growth substrate, and falls into a corresponding chip bonding area after the top wall breaks under a pressure, and electrodes of each of the light-emitting chips are coupled with pads in a corresponding chip bonding area.

The above light-emitting component is manufactured with the above circuit-board component. During transferring of light-emitting chips onto the circuit-board component, it is not required to transfer light-emitting chips onto a temporary substrate from the growth substrate and then onto the transfer substrate from the temporary substrate, and also not required to manufacture the temporary substrate and the transfer substrate, such that a chip transfer efficiency is higher, and a transfer cost is lower, and thus a manufacturing efficiency of the light-emitting component is higher, and a manufacturing cost is lower.

Based on the same inventive concept, the disclosure further provides a manufacturing method of the above circuit-board component. The manufacturing method of the above circuit-board component includes the following. A sacrificial layer is formed on the circuit board, where the sacrificial layer includes multiple sacrificial-layer units separated from each other, and each of the multiple sacrificial-layer units is covered on a corresponding chip bonding area. The weakening layer that is covered on each of the multiple sacrificial-layer units is formed on the circuit board. Each of the multiple sacrificial-layer units is removed, where a space occupied by each of the multiple sacrificial-layer units is defined as the cavity.

The circuit-board component is manufactured according to the manufacturing method of the above circuit-board component. During transferring of light-emitting chips onto the circuit-board component, it is not required to transfer light-emitting chips onto a temporary substrate from the growth substrate and then onto the transfer substrate from the temporary substrate, and also not required to manufacture the temporary substrate and the transfer substrate, such that a chip transfer efficiency is higher, and a transfer cost is lower.

Based on the same inventive concept, the disclosure further provides a manufacturing method of the above light-emitting component. The manufacturing method of the above light-emitting component includes the following. A surface of the growth substrate grown with the light-emitting chips is aligned and attached to the weakening layer on the circuit board, where the light-emitting chip is contacted with a corresponding top wall after alignment and attachment. The light-emitting chip, on the growth substrate, corresponding to the top wall is stripped off from the growth substrate, and the growth substrate is removed, where the light-emitting chip stripped off is born on the top wall. A pressure is applied to the top wall where the light-emitting chip is born, to make the top wall break and make the light-emitting chip born on the top wall fall into a corresponding chip bonding area. Electrodes of the fallen light-emitting chip are coupled with pads in a corresponding chip bonding area.

According to the manufacturing method of the above light-emitting component, during transferring of light-emitting chips onto the circuit-board component, it is not required to transfer light-emitting chips onto a temporary substrate from the growth substrate and then onto the transfer substrate from the temporary substrate, and also not required to manufacture the temporary substrate and the transfer substrate, such that a chip transfer efficiency is higher, and a transfer cost is lower, and thus a manufacturing efficiency of the light-emitting component is higher, and a manufacturing cost is lower.

Based on the above, solutions capable of solving the above technical problems are provided in the disclosure, which will be explained in details in the following implementations.

A circuit-board component is provided in the disclosure. The circuit-board component includes a circuit board. The circuit board of implementations may be a display backplane, a circuit board for lighting, a flexible circuit board, a rigid circuit board, or the like. If the circuit board is a display backplane, the display backplane may be, but is not limited to, a glass backplane or a printed circuit board (PCB).

In the implementation, multiple chip bonding areas are defined on the circuit board, and each of the multiple chip bonding areas is provided with pads corresponding to electrodes of a light-emitting chip. It can be understood that, the number of the chip bonding areas and arrangement thereof on the circuit board can be flexibly set according to application requirements. For example, the chip bonding areas can be arranged in an array on the circuit board, and can also be flexibly arranged according to other rules or even according to requirements. In some application examples, for facilitating direct transferring of light-emitting chips onto the circuit board from a growth substrate, arrangement of the chip bonding areas on the circuit board can correspond to arrangement and locations of corresponding light-emitting chips on the growth substrate.

It can be understood that in the implementation, the chip bonding area is not limited to be bonded with a light-emitting chip, where the light-emitting chip can also be replaced, according to application requirements, with other electronic chips such as resistor chips, capacitor chips, driving chips, or control chips, which will not be listed herein.

It can be understood that in the implementation, the light-emitting chip may be a micro light-emitting chip. For example, the light-emitting chip may include, but is not limited to, at least one of a mini LED chip or a micro LED chip, and may also be a normal light-emitting chip which has a size larger than or equal to 200 μm. Furthermore, in the implementation, the light-emitting chip may be a front-mounted light-emitting chip, a flipped light-emitting chip, or a vertical light-emitting chip, which can be flexibly set according to application requirements. In the implementation, a light-exiting surface of the light-emitting chip grown on the growth substrate is attached to the growth substrate.

In the implementation, the circuit-board component further includes a weakening layer disposed on the circuit board and defining multiple cavities, where the multiple cavities defined by the weakening layer are isolated from each other by the weakening layer, one chip bonding area corresponds to one cavity, and corresponding areas of the weakening layer form side walls and a top wall of each of the multiple cavities. The top wall of each of the multiple cavities is used to bear a light-emitting chip detached from a growth substrate, and after the top wall breaks under an external pressure, the light-emitting chip born on the top wall falls into a cavity and then falls into a chip bonding area corresponding to the cavity.

In the implementation, for improving a transfer efficiency of light-emitting chips, a distance H between a surface of the top wall of each cavity away from the circuit board and the circuit board is set to be greater than or equal to a height of the light-emitting chip. Therefore, after transferring the light-emitting chips onto the circuit board first time, subsequently, when it is further required to transfer chips into other chip bonding areas on the circuit board, the light-emitting chip transferred is located in the cavity, and the distance H between the surface of the top wall of each cavity away from the circuit board and the circuit board is greater than or equal to the height of the light-emitting chip, that is, a height of a side wall of each cavity is greater than the height of the light-emitting chip, such that the light-emitting chip transferred will not interfere with other chips on the growth substrate during subsequent transferring, thereby ensuring subsequently normal transferring of light-emitting chips. As can be seen, during transferring of light-emitting chips onto the circuit-board component, it is not required to transfer light-emitting chips onto a temporary substrate from the growth substrate and then onto the transfer substrate from the temporary substrate, and also not required to manufacture the temporary substrate and the transfer substrate, such that a transfer efficiency is higher, and a transfer cost is lower.

For ease of understanding, the following will exemplarily depict a circuit-board component provided in the implementation with reference to accompanying drawings.

As illustrated in FIG, 2, an exemplary circuit-board component includes a circuit board 4, where multiple chip bonding areas 40 are defined on the circuit board 4, and each of the multiple chip bonding areas 40 is provided with pads 41 corresponding to electrodes of a light-emitting chip. As illustrated in FIG. 2, the circuit-board component further includes a weakening layer 5 disposed on the circuit board 4 and defining multiple cavities 50, where the multiple cavities 50 are isolated from each other by the weakening layer 5, and corresponding areas of the weakening layer 5 form a top wall 51 and side walls 52 of each of the multiple cavities 50. As illustrated in FIG. 2, a distance H between a surface of the top wall 51 of each cavity away from the circuit board 4 and the circuit board 4 is greater than or equal to a height of the light-emitting chip. In the implementation, if light-emitting chips to be transferred onto the circuit board 4 are different in height, the above “height of the light-emitting chip” is a maximum height among heights of the light-emitting chips.

For the circuit-board component illustrated in FIG. 2, side walls 52 of respective cavities 50 are separated from each other. However, it should be understood that in the implementation, side walls 52 of respective cavities 50 may also be connected with each other, for example, see FIG. 3. In some application examples, part of side walls 52 of respective cavities 50 may also be connected with each other, while another part of the side walls 52 of respective cavities 50 may also be separated from each other. That is, in the application example illustrated in FIG. 3, part of the weakening layer is filled in a gap between two adjacent chip bonding areas.

In addition, it should be understood that in the implementation, a shape of the cavity 50 can be flexibly set. For example, a cross section of the cavity in a thickness direction (z) of a circuit board 4 may be in a shape of a rectangle, see FIG. 2 and FIG. 3. Alternatively, the cross section of the cavity in the thickness direction (z) of the circuit board 4 may also be in a shape of an arc, a trapezoid, or other regular shapes, or may also be in an irregular shape according to needs, which is not limited herein.

In some examples, a height of the cavity 50 may be greater than or equal to the height of the light-emitting chip, or slightly less than the height of the light-emitting chip, as long as it can he ensured that after the top wall 51 of the cavity 50 breaks, the light-emitting chip can fall into the corresponding chip bonding area 40 through the cavity 50, that is, as long as a size of the cavity 50 is adapted to a size of the light-emitting chip, so that the light-emitting chip can fall into the corresponding chip bonding area 40 through the cavity 50 after the top wall 51 of the cavity 50 breaks.

In some examples, when transferring the light-emitting chip onto the circuit board, the top wall 51 of the cavity 50 breaks, but the side walls 52 of the cavity 50 may be kept according needs. If the side walls of the cavity 50 are kept, the weakening layer 5 may be a light blocking layer that is non-transparent. In this case, the side walls of the cavity 50 can also play a role in light blocking, thereby avoiding occurrence of optical crosstalk between light-emitting chips in adjacent chip bonding areas 40 on the circuit board 4, and thus improving display or lighting effect. For example, in some application scenarios, the weakening layer 5 is a black adhesive layer.

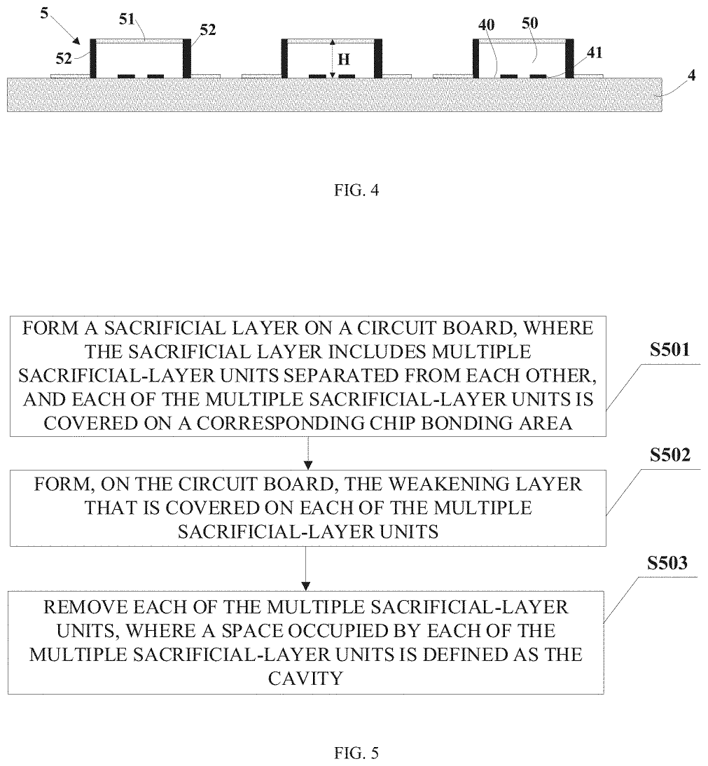

It should be understood that, in some examples, areas of the weakening layer 5 forming the top wall 51 and the side walls 52 of the cavity 50 may be made of the same material, for example, see FIG. 2 and FIG. 3, In other application examples, the areas of the weakening layer 5 forming the top wall 51 and the side walls 52 of the cavity 50 may also be made of different materials, for example, see FIG. 4, the side walls 52 may be made of a non-transparent material, while the top wall 51 may be made of a transparent material or a non-transparent material.

In addition, it should be understood that in the implementation, one chip bonding area 40 may be provided with one light-emitting chip, or provided with multiple light-emitting chips according to needs. If multiple light-emitting chips are provided, transferring of the multiple light-emitting chips is complete in one chip transfer process.

In some examples, the weakening layer 5 may be a hot-melt adhesive (HMA) layer. For example, the HMA may be, but is not limited to, a pyrolytic adhesive or a non-conductive adhesive. As such, subsequently, when heating electrodes of the light-emitting chip to weld with corresponding pads, a broken adhesive part falling into the cavity 50 will be melted under heating and then accumulated on a solder-free area, such that welding between the electrodes of the light-emitting chip and the pads may not be affected, and light exiting of the light-emitting chip may also be not affected. In some examples, the weakening layer 5 may also be made of a sacrificial material that can be eliminated subsequently, where the sacrificial material may be a non-conductive material. After electrodes of the light-emitting chip are welded with corresponding pads, the weakening layer can be eliminated.

In one example, the HMA layer is sticky, such that when the top wall 51 bears the light-emitting chip from the growth substrate, the light-emitting chip can be fixed due to stickiness of the top wall 5l, which is beneficial for separating the light-emitting chip from the growth substrate, and can also make the light-emitting chip more stably born on the top wall 51.

In some examples, if side walls 52 of each cavity 50 are kept after the light-emitting chip is transferred onto the circuit board 4, at least one of an external side surface or an internal side surface of the side wall 52 may be a reflective surface. That is, in this case, the cavity 50 and the side walls 52 of the cavity 50 can constitute a reflective cup, thereby improving a light-exiting efficiency of the light-emitting chip.

In the implementation, thickness and material of the top wall 51 of each cavity 50 can be flexibly selected and set, as long as the top wall 51 can bear the light-emitting chip, and the light-emitting chip is not damaged after the top wall 51 breaks due to applying a pressure F. For example, in one application example, if the weakening layer 5 is made of an HMA, a thickness of the top wall 51 formed may be less than or equal to 5 μm, e.g., the thickness may be 5 μm, 4 μm, or 3 μm.

As can be seen, according to the circuit-board component provided in the implementation, during transferring of chips onto the circuit board 4, a surface of the growth substrate grown with light-emitting chips can be directly aligned and attached to the weakening layer 5, and a light-emitting chip to-be-transferred is stripped off from the growth substrate, such that the light-emitting chip is born on a top wall 51 of a corresponding cavity 50. Then a pressure F is applied to the top wall 51, to make the top wall 51 break and make the light-emitting chip directly fall into a corresponding chip bonding area 40. Since the distance between the surface of the top wall 51 away from the circuit board 4 and the circuit board is greater than or equal to the height of the light-emitting chip, and the light-emitting chip transferred is located in the cavity 50, subsequently, when it is further required to transfer chips into other chip bonding areas on the circuit board 4, the light-emitting chip transferred will not interfere with other chips on the growth substrate during subsequent transferring, thereby ensuring subsequently normal transferring of light-emitting chips. In a whole chip transferring process, it is not required to transfer light-emitting chips onto a temporary substrate from the growth substrate and then onto the transfer substrate from the temporary substrate, and also not required to manufacture the temporary substrate and the transfer substrate, such that a transfer efficiency is higher, and a transfer cost is lower.

In another optical implementation:

For ease of understanding, in the implementation, the following will illustrate an exemplary manufacturing method of the above circuit-board component. As illustrated in FIG. 5, the method includes but is not limited to the following.

At S501, a sacrificial layer is formed on a circuit board, where the sacrificial layer includes multiple sacrificial-layer units separated from each other, and each of the multiple sacrificial-layer units is covered on a corresponding chip bonding area.

In the implementation, size and shape of a cavity formed on the circuit board is basically determined according to size and shape of each sacrificial-layer unit. Therefore, for details of shape and size of the sacrificial-layer unit, reference can be made to the above illustration of shape and size of the cavity, which will not be repeated herein.

In the implementation, a forming manner and a specific material of the sacrificial-layer unit can be flexibly selected. For example, in some examples, the sacrificial-layer unit may be a photoresist-layer unit or a polyvinyl alcohol (PVA)-layer unit, which is not limited herein, as long as the sacrificial-layer unit can be eliminated after the weakening layer is formed on the sacrificial-layer unit.

At S502, the weakening layer that is covered on each of the multiple sacrificial-layer units is formed on the circuit board.

In the implementation, the weakening layer is not totally covered on each sacrificial-layer unit, i.e., at least one side surface of each sacrificial-layer unit is not covered by the weakening layer, to act as a channel for eliminating the sacrificial-layer unit.

At S503, each of the multiple sacrificial-layer units is removed, where a space occupied by each of the multiple sacrificial-layer units is defined as a cavity.

For example, if the sacrificial-layer unit is made of photoresist, the photoresist can be washed off to form a cavity, i.e., to form a hollow structure.

For ease of understanding, for example, a weakening layer is an HMA layer and a sacrificial-layer unit is a photoresist-layer unit, the following will exemplarily depict a manufacturing process of the circuit-board component illustrated in FIG. 2 and a manufacturing process of the circuit-board component illustrated in FIG. 3.

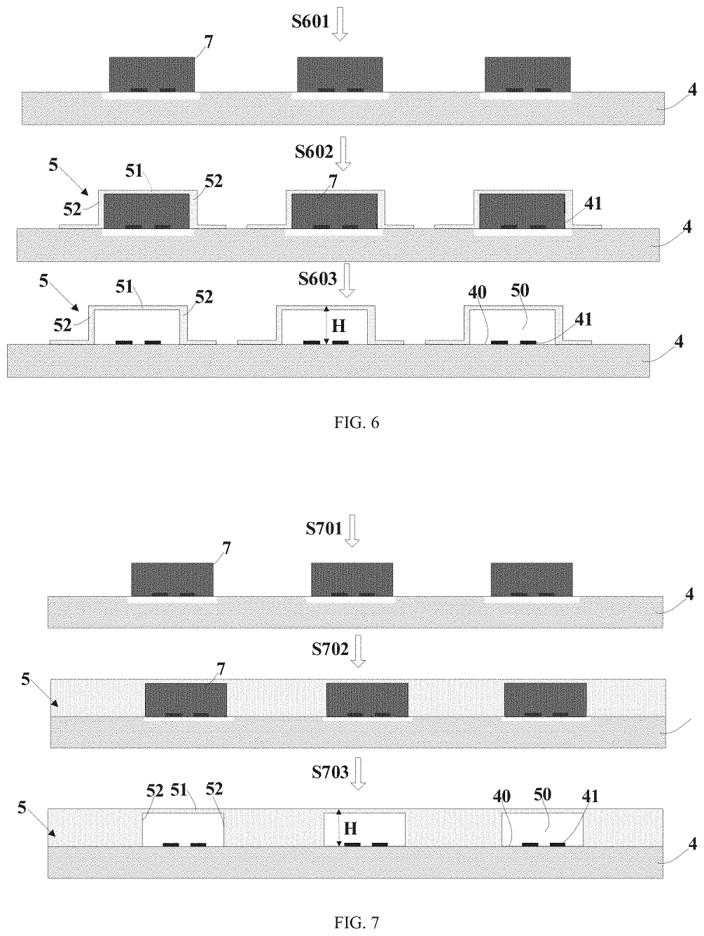

As illustrated in FIG. 6, the manufacturing process of the circuit-board component illustrated in FIG. 2 includes, but is not limited to, the following.

At S601, sacrificial-layer units 7 respectively covered on each chip bonding area are formed on a circuit board 4.

At S602, a weakening layer, i.e., an HMA layer, covered on each of the sacrificial-layer units 7 is formed on the circuit board 4. In the implementation, the weakening layer covered on each of the sacrificial-layer units 7 is inconsecutive. During manufacturing of the circuit-board component illustrated in FIG. 4, a top wall 51 and side walls 52 are respectively disposed on a top surface and side surfaces of each of the sacrificial-layer units 7.

At S603, after the weakening layer 5 has solidified, each of the sacrificial-layer units 7 is washed off, and a space occupied by each of the sacrificial-layer units 7 is defined as a cavity 50.

As illustrated in FIG. 7, the manufacturing process of the circuit-board component illustrated in FIG. 3 includes, but is not limited to, the following.

At S701, sacrificial-layer units 7 respectively covered on each chip bonding area are formed on a circuit board 4.

At S702, a weakening layer, i.e., an HMA layer, covered on each of the sacrificial-layer units 7 is formed on the circuit board 4. In the implementation, the weakening layer covered on each of the sacrificial-layer units 7 is consecutive, that is, the weakening layer is filled in a gap between adjacent sacrificial-layer units, where the weakening layer is a whole layer of HMA.

At S703, after the weakening layer 5 has solidified, each of the sacrificial-layer units 7 is washed off, and a space occupied by each of the sacrificial-layer units 7 is defined as a cavity 50.

As can be seen, the manufacturing method of the circuit-board component provided in the implementation is simple, convenient, and efficient. During transferring of light-emitting chips onto the circuit-board component manufactured, it is not required to transfer light-emitting chips onto a temporary substrate from the growth substrate and then onto the transfer substrate from the temporary substrate, and also not required to manufacture the temporary substrate and the transfer substrate, such that a chip transfer efficiency is higher, and a transfer cost is lower.

In yet another implementation:

A light-emitting component is provided in the implementation. The light-emitting component includes the circuit-board component of the foregoing implementations and light-emitting chips in the multiple chip bonding areas. During transferring of the light-emitting chips onto the circuit board, each of the light-emitting chips is born on a top wall of a corresponding area after being detached from the growth substrate, and falls into a corresponding chip bonding area after the top wall breaks under a pressure, and electrodes of each of the light-emitting chips are coupled with pads in a corresponding chip bonding area.

In an example, the light-emitting component may be a display panel, and in this case, the circuit board is a display backplane. In this case, the light-emitting chip may be a light-emitting chip of one color (e.g., a blue light-emitting chip), and then a red light and a green light are obtained by means of corresponding light conversion layers (e.g., a quantum dot film), to achieve color display. In the example, the light-emitting chip includes a first light-emitting chip, a second light-emitting chip, and a third light-emitting chip which are different in light-emitting color, where the light-emitting color includes a red, a green, and a blue. For example, the first light-emitting chip is a red light-emitting chip that emitting a red light, the second light-emitting chip is a blue light-emitting chip that emitting a blue light, and the third light-emitting chip is a green light-emitting chip that emitting a green light.

For ease of understanding, the following will exemplarily depict a light-emitting component with reference to several exemplary drawings of the light-emitting component,

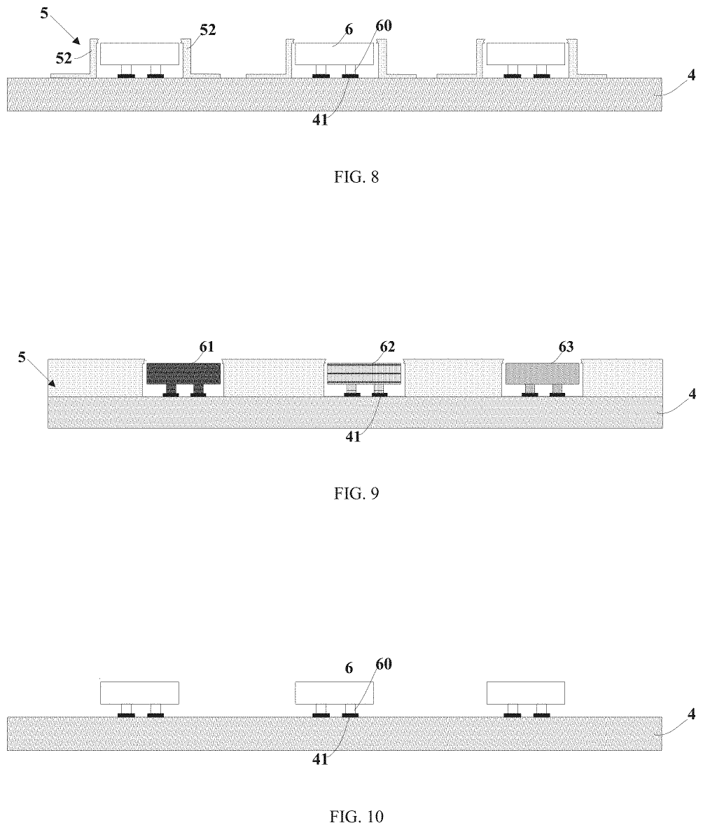

As illustrated in FIG. 8, an exemplary light-emitting component includes a circuit board 4 and light-emitting chips 6 disposed on the circuit board 4 and falling into multiple cavities 50, where electrodes 60 of each of the light-emitting chips 6 are electronically coupled with pads 41 in a corresponding chip bonding area 40, e.g., the electrodes 60 are electronically coupled with the pads 41 through welding or a conductive adhesive. For the light-emitting component illustrated in FIG. 8, side walls 52 of each of the multiple cavities 50 are kept, where the side walls 52 can play a role in at least one of light blocking, reflection, or refraction. For the light-emitting component illustrated in FIG. 8, side walls 52 of respective cavities 50 are separated from each other.

FIG. 9 illustrates another example of the light-emitting component. Compared with the light-emitting component illustrated in FIG. 8, main differences lie in that: the light-emitting component illustrated in FIG. 9 includes a first light-emitting chip 61, a second light-emitting chip 62, and a third light-emitting chip 63, and a side wall 52 is fully filled in a gap between adjacent chip bonding areas 40. The side wall 52 may also play a role in at least one of light blocking, reflection, refraction, etc.

FIG. 10 illustrates yet another example of the light-emitting component. Compared with the light-emitting components illustrated in FIG. 8 and FIG. 9, a main difference lies in that: after electrodes of a light-emitting chip 6 are bonded with corresponding pads 41, a weakening layer is removed, i.e., a side wall 52 is also removed.

Since the light-emitting component provided in the implementation is manufactured with the above circuit-board component, in a manufacturing process, during transferring of light-emitting chips onto the circuit-board, it is not required to transfer light-emitting chips onto a temporary substrate from the growth substrate and then onto the transfer substrate from the temporary substrate, and also not required to manufacture the temporary substrate and the transfer substrate, such that a chip transfer efficiency is higher, and a transfer cost is lower, and thus a manufacturing efficiency of the light-emitting component is higher, and a manufacturing cost is lower.

In another optional implementation:

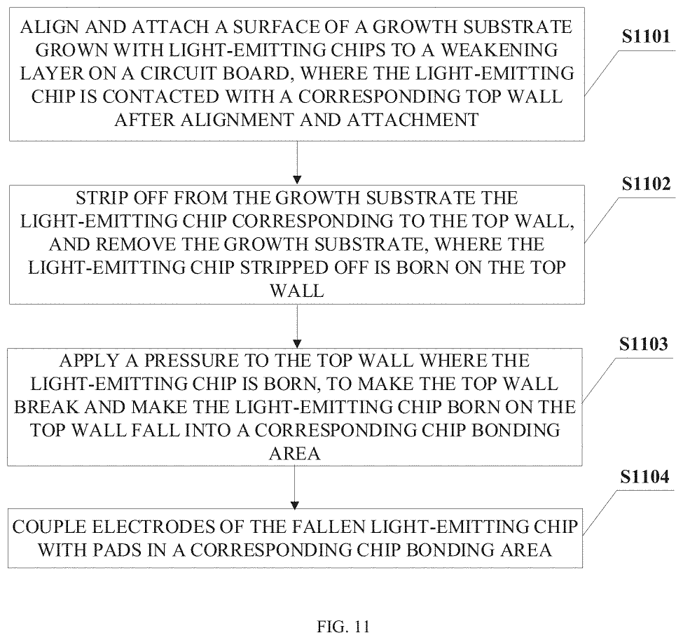

For ease of understanding, in the implementation, the following will take a manufacturing method of the light-emitting component of the above implementation as an example for illustration. As illustrated in FIG. 11, the method includes, but is not limited to, the following.

At S1101, a surface of a growth substrate grown with light-emitting chips is aligned and attached to a weakening layer on a circuit board, where the light-emitting chip is contacted with a top wall (i.e., the top wall is formed by the weakening layer) after alignment and attachment.

At S1102, the light-emitting chip, on the growth substrate, corresponding to the top wall is stripped off from the growth substrate, and the growth substrate is removed, where the light-emitting chip stripped off is born on the top wall, while a light-emitting chip unstripped off is removed together with the growth substrate. For example, the light-emitting chip can be stripped off from the growth substrate by laser lift off (LLO), which is not limited herein.

At S1103, a pressure is applied to the top wall where the light-emitting chip is born, to make the top wall break and make the light-emitting chip born on the top wall fall into a corresponding chip bonding area.

At S1104, electrodes of the fallen light-emitting chip are coupled with pads in a corresponding chip bonding area.

As can be seen, during manufacturing of the light-emitting component, a surface of the growth substrate grown with light-emitting chips can be directly aligned and attached to the weakening layer, and a light-emitting chip to-be-transferred is stripped off from the growth substrate, such that the light-emitting chip is born on a top wall of a corresponding cavity. Then a pressure is applied to the top wall, to make the top wall break and make the light-emitting chip directly fall into a corresponding chip bonding area. Since the distance between the surface of the top wall away from the circuit board and the circuit board is greater than or equal to the height of the light-emitting chip, and the light-emitting chip transferred is located in the cavity, subsequently, when it is further required to transfer chips into other chip bonding areas on the circuit board, the light-emitting chip transferred will not interfere with other chips on the growth substrate during subsequent transferring, As such, in the whole chip transferring process, a temporary substrate, a transfer substrate, or a transfer head are no longer needed, and thus a manufacturing efficiency is higher, and a manufacturing cost is lower.

In a micro LED display field, the number of micro LED chips transferred onto a display backplane is basically tens of thousands or more. Therefore, after transferring of micro LED chips is completed, it is difficult to detect a defective chip on the display backplane. Even if the defective chip is detected, the defective chip is difficult to be repaired. Even if the defective chip can be repaired, a repair process is quite complex. In addition, currently, during transferring of micro LED chips, on all micro LED chips on the growth substrate is performed at one time, and all micro LED chips are transferred onto a temporary substrate, causing that qualities of chips on a prepared micro LED display device are uncontrollable, and thus a repair cost is higher. Furthermore, since light-emitting wavelengths of micro LED chips cannot be preselected, uniformity of light emission of a prepared display device may be poor. Based on the above, in the implementation, before transferring light-emitting chips on the growth substrate onto the circuit board, e.g., before aligning and attaching the surface of the growth substrate grown with the light-emitting chips to the weakening layer On the circuit board, the method further includes the following.

Each of the light-emitting chips on the growth substrate is detected, and an unqualified light-emitting chip is removed from the growth substrate, such that light-emitting chips kept on the growth substrate are qualified light-emitting chips. As such, transferring of a defective light-emitting chip onto the circuit board can be avoided as much as possible, and detection and repairing of the defective light-emitting chip can be avoided as much as possible, thereby improving a product quality and reducing a maintenance cost.

In the implementation, detecting each of the light-emitting chips on the growth substrate may include, but is not limited to, at least one of: detecting an appearance of each of the light-emitting chips or detecting an optical characteristic of each of the light-emitting chips.

For example, in an example, an optical characteristic and an appearance quality of each of the light-emitting chips on the growth substrate can be detected in advance through a detection manner, for example, the detection manner includes micro photoluminescence (micro PL)/automated optical inspection (AOI), to generate corresponding mapping data, thereby determining a unqualified light-emitting chip from the light-emitting chips and removing the unqualified light-emitting chip from the growth substrate.

In some examples, detecting the optical characteristic of each of the light-emitting chips may include but is not limited to the following. Detect a main wavelength of each of the light-emitting chips. A light-emitting chip, which corresponds to a difference between a main wavelength of the light-emitting chip and a preset standard main wavelength greater than a preset difference, is determined as the unqualified light-emitting chip. As such, consistency of main wavelengths of light-emitting chips kept on the growth substrate is relatively good, thereby further improving uniformity of light emission of the light-emitting component and a display effect or a lighting effect.

For ease of understanding, in the implementation, the following will take one application scenario as an example for illustration. In the example, the growth substrate includes a first growth substrate grown with a first light-emitting chip (e.g., a red light-emitting chip), a second growth substrate grown with a second light-emitting chip (e.g., a green light-emitting chip), and a third growth substrate grown with a third light-emitting chip (e.g., a blue light-emitting chip). In the example, aligning and attaching the surface of the growth substrate grown with the light-emitting chips to the weakening layer on the circuit board includes the following. The first growth substrate, the second growth substrate, and third growth substrate are aligned and attached to the weakening layer on the circuit board one by one, and after a light-emitting chip on an aligned and attached growth substrate falls into a corresponding chip bonding area, a next growth substrate is aligned and attached to the weakening layer on the circuit board.

Coupling the electrodes of the fallen light-emitting chip with the pads in the corresponding chip bonding area may include, but is not limited to, the following two manners.

In manner 1, after the first light-emitting chip, the second light-emitting chip, and the third light-emitting chip respectively falls into a corresponding chip bonding area, electrodes of each of the first light-emitting chip, the second light-emitting chip, and the third light-emitting chip are welded with pads corresponding to the electrodes in a welding process.

In manner 2, before aligning and attaching the next growth substrate to the weakening layer on the circuit board after the light-emitting chip (e.g., the first light-emitting chip) on the aligned and attached growth substrate falls into the corresponding chip bonding area, the method further includes: welding electrodes of the light-emitting chip (e.g., the first light-emitting chip) fallen into the corresponding chip bonding area with pads corresponding to the electrodes.

In the following, a process that the first light-emitting chip, the second light-emitting chip, and the third light-emitting chip are transferred onto the circuit board one by one will be exemplarily depicted.

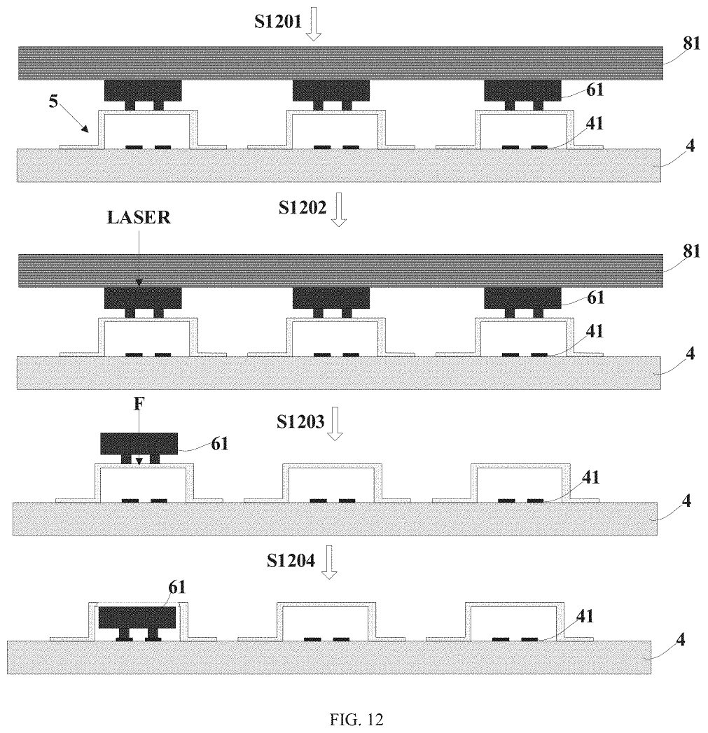

As illustrated in FIG. 12, a process that the first light-emitting chip is transferred onto the circuit board includes the following.

At S1201, a surface of a first growth substrate 82 grown with first light-emitting chips 61 is aligned and attached to a. weakening layer 5 on a circuit board 4, where the first light-emitting chip 61 is contacted with an area where the weakening layer 5 forms a top wall 51 after alignment and attachment.

At S1202, the first light-emitting chip 61, on the first growth substrate 81, corresponding to the top wall 51 is stripped off (e.g., through LLO with 248 nm or 266 nm laser), and the first growth substrate 81 is removed, where the first light-emitting chip 61 stripped off is born on the top wall 51, while a first light-emitting chip 61 unstripped off is removed together with the first growth substrate 81.

At S1203, a pressure F is applied to the top wall 51 where the first light-emitting chip 61 is born, to make the top wall 51 break.

At S1204, after the top wall 51 breaks, the first light-emitting chip 61 born on the top wall 51 falls into a corresponding chip bonding area.

In this operation, electrodes of each of the fallen first light-emitting chips 61 can be welded with pads 41 in a corresponding chip bonding area; alternatively, after other light-emitting chips are transferred, electrodes of each of the fallen first light-emitting chips 61 and other fallen light-emitting chips are welded with pads 41 in a corresponding chip bonding area.

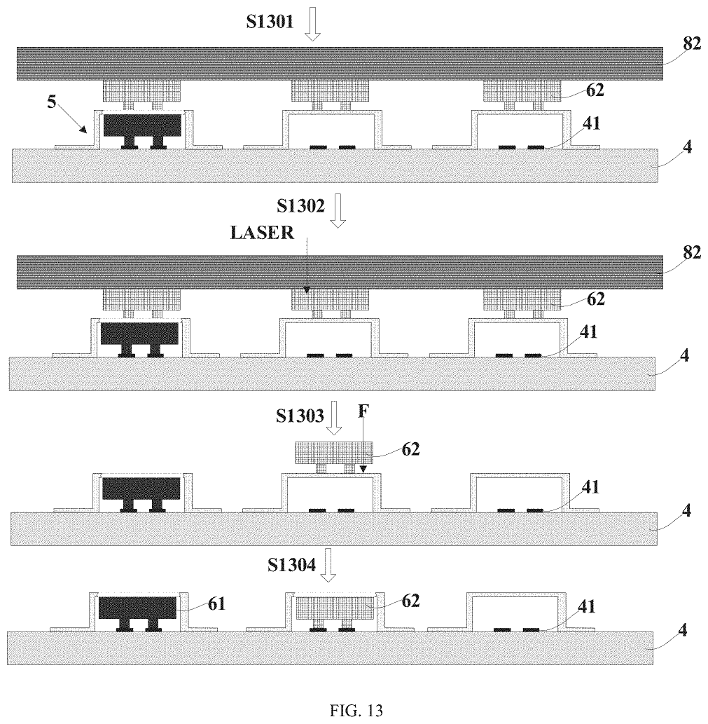

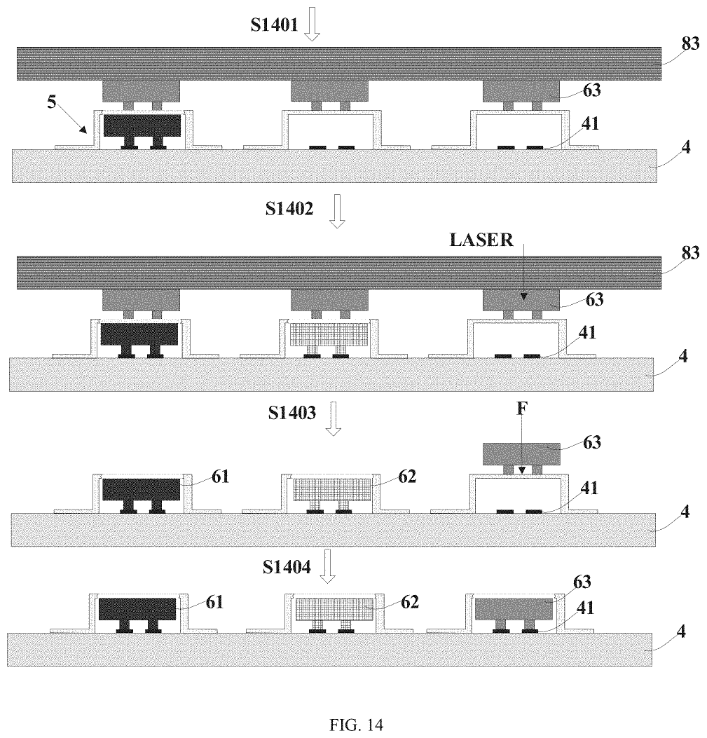

As illustrated in FIG. 13, a process that the second light-emitting chip is transferred onto the circuit board includes the following.

At S1301, a surface of a second growth substrate 82 grown with second light-emitting chips 62 is aligned and attached to a weakening layer 5 on a circuit board 4, where the second light-emitting chip 62 is contacted with an area where the weakening layer 5 forms the top wall 51 after alignment and attachment. In this operation, the transferred first light-emitting chip 61 is located in a cavity 50, and therefore, the first light-emitting chip 61 does not obstruct or interfere with the second light-emitting chip 62 on the second growth substrate 82.

At S1302, the second light-emitting chip 62, on the second growth substrate 82, corresponding to the top wall 51 is stripped off and the second growth substrate 82 is removed, where the second light-emitting chip 62 stripped off is born on the top wall 51, while a second light-emitting chip 62 unstripped off is removed together with the second growth substrate 82.

At S1303, a pressure F is applied to the top wall 51 where the second light-emitting chip 62 is born, to make the top wall 51 break.

At S1304, after the top wall 51 breaks, the second light-emitting chip 62 born on the top wall 51 falls into a corresponding chip bonding area.

In this operation, electrodes of each of the fallen second light-emitting chips 62 can be welded with pads 41 in a corresponding chip bonding area; alternatively, after other light-emitting chips are transferred, electrodes of each of the fallen second light-emitting chips 62 and other fallen light-emitting chips are welded with pads 41 in a corresponding chip bonding area.

As illustrated in FIG, 14, a process that the third light-emitting chip is transferred onto the circuit board includes the following.

At S1401, a surface of a third growth substrate 83 grown with third light-emitting chips 63 is aligned and attached to a weakening layer 5 on a circuit board 4, where the third light-emitting chip 63 is contacted with an area where the weakening layer 5 forms the top wall 51 after alignment and attachment. In this operation, the transferred first light-emitting chip 61 and the transferred second light-emitting chip 62 are located in corresponding cavities 50, and therefore, the first light-emitting chip 61 and the second light-emitting chip 62 do not obstruct or interfere with the third light-emitting chip 63 on the third growth substrate 83.

At S1402, the third light-emitting chip 63, on the third growth substrate 83, corresponding to the top wall 51 is stripped off, and the third growth substrate 83 is removed, where the third light-emitting chip 63 stripped off is born on the top wall 51, while a third light-emitting chip 63 unstripped off is removed together with the third growth substrate 83.

At S1403, a pressure F is applied to the top wall 51 where the third light-emitting chip 63 is born, to make the top wall 51 break.

At S1404, after the top wall 51 breaks, the third light-emitting chip 63 born on the top wall 51 falls into a corresponding chip bonding area.

In this operation, electrodes of each of the fallen first light-emitting chips 61, the fallen second light-emitting chips 62, and the fallen third light-emitting chips 63 may be welded with pads 41 in a corresponding chip bonding area at once, thereby improving a welding efficiency and a welding effect.

It should be noted that, the above merely illustrates one possible transfer order of three-color LED chips, and the disclosure does not limit the transfer order of the three-color LED chips. That is, after transferring of one color type of LED chips is completed, another color type of LED chips is transferred. In addition, welding of LED chips may be performed after transferring of one color type of LED chips is completed, or three-color LED chips are welded at one time after being transferred, which is not limited in the disclosure.

As can be seen, during transferring of the above chips, it is not required to transfer light-emitting chips onto a temporary substrate from the growth substrate and then onto the transfer substrate from the temporary substrate, and also not required to manufacture the temporary substrate and the transfer substrate, such that a chip transfer efficiency is higher, and a transfer cost is lower, and thus a manufacturing efficiency of the light-emitting component is higher, and a manufacturing cost is lower.

A display screen is further provided in the implementation. The display screen may be a flexible display screen or a rigid display screen. The display screen may be in a regular shape such as rectangle, circle, or ellipse, or may also be in an irregular shape. The display screen may include a display-screen frame and the display panel illustrated in the foregoing examples, where the display panel is manufactured with the above light-emitting component, and the display panel is fixed in the display-screen frame. It should be understood that, the display screen in the implementation can be applied to various electronic devices such as a display, a computer, a cell phone, a smart watch, an in-vehicle device, or a billboard. For the display screen, a manufacturing efficiency is higher, a cost is lower, a yield rate is higher, a light-exiting efficiency is higher, and a display effect is better.

It should be understood that, the application of the disclosure is not limited to the foregoing exemplary implementations. Those of ordinary skill in the art may make improvements or equivalent substitutions to the disclosure according to the above descriptions, and all these improvements and equivalent substitutions, however, shall all be encompassed within the protection scope of the appended claims of the disclosure.

What is claimed is:

1. A circuit-board component, comprising:
a circuit board, wherein a plurality of chip bonding areas are defined on the circuit board, and each of the plurality of chip bonding areas is provided with pads corresponding to electrodes of a light-emitting chip; and
a weakening layer disposed on the circuit board and defining a plurality of cavities, wherein
the plurality of cavities are isolated from each other by the weakening layer, one chip bonding area corresponds to one cavity, and the weakening layer forms side walls and a top wall of each of the plurality of cavities;
the top wall is used to bear a light-emitting chip detached from a growth substrate, and after the top wall breaks under a pressure, the light-emitting chip born falls into a corresponding chip bonding area; and
a distance between a surface of the top wall away from the circuit board and the circuit board is greater than or equal to a height of the light-emitting chip. The circuit-board component of claim 1, wherein the circuit board is a display backplane.

3. The circuit-board component of claim 1, wherein the weakening layer is a hot-melt adhesive (HMA) layer.

4. The circuit-board component of claim 1, wherein the weakening layer is a light blocking layer which is non-transparent.

5. The circuit-board component of claim 1, wherein an internal side surface and/or an external side surface of each of the side walls is a reflective surface.

6. The circuit-board component of claim 1, wherein the top wall has a thickness less than or equal to 5 μm.

7. The circuit-board component of claim 1, wherein part of the weakening layer is filled in a gap between two adjacent chip bonding areas among the plurality of chip bonding areas.

8. The circuit-board component of claim 3, wherein the HMA layer has stickiness.

9. A light-emitting component, comprising:
a circuit-board component, comprising:
a circuit board, wherein a plurality of chip bonding areas are defined on the circuit board, and each of the plurality of chip bonding areas is provided with pads corresponding to electrodes of a light-emitting chip; and
a weakening layer disposed on the circuit board and defining a plurality of cavities, wherein
the plurality of cavities are isolated from each other by the weakening layer, one chip bonding area corresponds to one cavity, and the weakening layer forms side walls and a top wall of each of the plurality of cavities;
the top wall is used to bear a light-emitting chip detached from a growth substrate, and after the top wall breaks under a pressure, the light-emitting chip born falls into a corresponding chip bonding area; and
a distance between a surface of the top wall away from the circuit board and
the circuit board is greater than or equal to a height of the light-emitting chip; and
light-emitting chips in the plurality of chip bonding areas, wherein each of the light-emitting chips is born on the top wall after being detached from the growth substrate, and falls into a corresponding chip bonding area after the top wall breaks under a pressure, and electrodes of each of the light-emitting chips are coupled with pads in a corresponding chip bonding area.

10. The light-emitting component of claim 9, wherein each of the light-emitting chips comprises at least one of a mini light-emitting diode (LED) chip or a micro LED chip.

11. The light-emitting component of claim 10, wherein the circuit board is a display backplane, each of the light-emitting chips comprises a first light-emitting chip, a second light-emitting chip, and a third light-emitting chip which are different in light-emitting color, wherein the light-emitting color comprises a red, a green, and a blue.

12. A manufacturing method of the circuit-board component of claim 1, comprising:
forming a sacrificial layer on the circuit board, wherein the sacrificial layer comprises a plurality of sacrificial-layer units separated from each other, and each of the plurality of sacrificial-layer units is covered on a corresponding chip bonding area;
forming, on the circuit board, the weakening layer that is covered on each of the plurality of sacrificial-layer units; and
removing each of the plurality of sacrificial-layer units, wherein a space occupied by each of the plurality of sacrificial-layer units is defined as the cavity.

13. The manufacturing method of the circuit-board component of claim 12, wherein each of the plurality of sacrificial-layer units is a photoresist-layer unit or a polyvinyl alcohol (PVA)-layer unit.

14. A manufacturing method of the light-emitting component of claim 9, comprising:
aligning and attaching a surface of the growth substrate grown with the light-emitting chips to the weakening layer on the circuit board, wherein the light-emitting chip is contacted with a corresponding top wall after alignment and attachment;
stripping off from the growth substrate the light-emitting chip corresponding to the top wall, and removing the growth substrate, wherein the light-emitting chip stripped off is born on the top wall;
applying a pressure to the top wall where the light-emitting chip is born, to make the top wall break and make the light-emitting chip born on the top wall fall into a corresponding chip bonding area; and
coupling electrodes of the fallen light-emitting chip with pads in a corresponding chip bonding area.

15. The manufacturing method of the light-emitting component of claim 14, wherein before aligning and attaching the surface of the growth substrate grown with the light-emitting chips to the weakening layer on the circuit board, the method further comprises:
detecting each of the light-emitting chips on the growth substrate; and
removing an unqualified light-emitting chip from the growth substrate.

16. The manufacturing method of the light-emitting component of claim 15, wherein detecting each of the light-emitting chips on the growth substrate comprises at least one of:
detecting an appearance of each of the light-emitting chips; or
detecting an optical characteristic of each of the light-emitting chips.

17. The manufacturing method of the light-emitting component of claim 16, wherein detecting the optical characteristic of each of the light-emitting chips comprises:
detecting a main wavelength of each of the light-emitting chips, and determining a light-emitting chip, that corresponds to a difference between a main wavelength of the light-emitting chip and a preset standard main wavelength greater than a preset difference, as the unqualified light-emitting chip.

18. The manufacturing method of the light-emitting component of claim 14, wherein
the growth substrate comprises a first growth substrate grown with a first light-emitting chip, a second growth substrate grown with a second light-emitting chip, and a third growth substrate grown with a third light-emitting chip, wherein the first light-emitting chip, the second light-emitting chip, and the third light-emitting chip are different in light-emitting color, and the light-emitting color comprises a red, a green, and a blue; and
aligning and attaching the surface of the growth substrate grown with the light-emitting chips to the weakening layer on the circuit board comprises:
aligning and attaching the first growth substrate, the second growth substrate, and third growth substrate to the weakening layer on the circuit board one by one, and after a light-emitting chip on an aligned and attached growth substrate falls into a corresponding chip bonding area, aligning and attaching a next growth substrate to the weakening layer on the circuit board.

19. The manufacturing method of the light-emitting component of claim 18, wherein coupling the electrodes of the fallen light-emitting chip with the pads in the corresponding chip bonding area comprises:
after the first light-emitting chip, the second light-emitting chip, and the third light-emitting chip respectively falls into a corresponding chip bonding area, welding electrodes of each of the first light-emitting chip, the second light-emitting chip, and the third light-emitting chip with pads corresponding to the electrodes during welding.

20. The manufacturing method of the light-emitting component of claim 18, wherein before aligning and attaching the next growth substrate to the weakening layer on the circuit board after the light-emitting chip on the aligned and attached growth substrate falls into the corresponding chip bonding area, the method further comprises:
welding electrodes of the light-emitting chip fallen into the corresponding chip bonding area with pads corresponding to the electrodes.
